(19) United States
(12) Patent Application Publication
(10) Pub. No.: US 2016/0077328 A1
(43) Pub. Date: Mar. 17, 2016

(54) ELECTRONIC DEVICE AND METHOD OF CONTROLLING LIGHT TRANSMITTANCE OF THE SAME

(71) Applicant: Samsung Display Co., Ltd., Yongin-city (KR)

(72) Inventors: Jong Ho CHONG, Hwaseong-si (KR); Dong Wook CHOI, Hwaseong-si (KR)

(21) Appl. No.: 14/674,829

(22) Filed: Mar. 31, 2015

(30) Foreign Application Priority Data
Sep. 15, 2014 (KR) 10-2014-0122152

(51) Int. Cl. G02B 26/02; G02F 1/1335; H01L 33/58

(52) U.S. Cl. CPC G02B 26/02; H01L 33/58; G02F 1/133526

(57) ABSTRACT

Provided are an electronic device and a method of controlling light transmittance of the same. The electronic device includes: a light source which provides light; and a variable light control member which adjusts transmittance of the provided light. The variable light control member includes: a base substrate including a plurality of unit areas; a thin-film transistor (TFT) which is disposed on the base substrate; and a deformable lens layer having lens portion disposed on the base substrate in association with at least one of the unit areas, the lens portion being deformable by a control signal of the TFT.

### CROSS-REFERENCE TO RELATED APPLICATION

This application claims priority from and the benefit under 35 U.S.C. §119(a) of Korean Patent Application No. 10-2014-0122152, filed on Sep. 15, 2014, which is incorporated herein by reference as if fully set forth herein.

### BACKGROUND

1. Field

Exemplary embodiments relate to an electronic device and a method of manufacturing the same.

2. Description

Examples of an electronic device include a lighting device and a display device. The display device may be implemented by using a liquid crystal display (LCD), an organic light-emitting display (OLED), etc.

An LCD generally includes two substrates which face each other and a liquid crystal layer, which is interposed between the two substrates. The LCD displays an image by adjusting the amount of light transmitted through the liquid crystal layer by controlling the arrangement of the liquid crystal molecules of the liquid crystal layer by applying voltages to electrodes (pixel electrodes and a common electrode) formed on the two substrates, respectively. The LCD is a non-emitting device in which an LCD panel including the substrates cannot emit light by itself. Therefore, a backlight unit is necessary to supply light to the LCD panel. The backlight unit typically includes one or more light sources, a circuit board which supplies power for driving the light sources, and optical members (such as a light guide member, a condensing member, a diffusion member, and a polarizing member) which are used to uniformly provide light from the light sources to the LCD panel.

An organic light-emitting display is a self-emitting display device and includes an organic light-emitting display panel having a plurality of pixels. The organic light-emitting display panel includes an organic light-emitting layer, which is made of an organic light-emitting material disposed between an anode and a cathode in each pixel. When positive and negative voltages are applied to these electrodes, respectively, holes injected from the anode move to the organic light-emitting layer via a hole injection layer and a hole transport layer, and electrons move from the cathode to the organic light-emitting layer via an electron injection layer and an electron transport layer. Accordingly, the electrons and the holes recombine in the organic light-emitting layer, and the recombination of the electrons and the holes generates excitons. When the excitons change from an excited state to a ground state, the organic light-emitting layer emits light. Accordingly, an image is displayed on the organic light-emitting display panel. Specifically, an image is displayed on the organic light-emitting display panel when the organic light-emitting layer of each pixel emits light at a luminance level corresponding to the magnitude of a current flowing from the anode to the cathode.

In order to satisfy the demands for thinner LCDs, various attempts have been made to reduce the number of optical members of a backlight unit or reduce the number of light sources of the backlight unit. However, reducing the number of optical members or reducing the number of light sources makes it difficult to provide light with more uniform transmittance to an LCD panel, resulting in a deteriorated image with non-uniform luminance.

In addition, since an organic light-emitting layer of an organic light-emitting display emits light in response to a current flowing from an anode to a cathode in each pixel, the magnitude of the current flowing from the anode to the cathode may differ in each pixel due to various reasons, e.g., unwanted internal resistance. In this case, the transmittance of light emitted from an organic light-emitting display panel may become non-uniform. Thus, the luminance of an image may be non-uniform and the image quality may be unsatisfactory.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an electronic device capable of adjusting the transmittance of light to make the luminance of an image more uniform in a display plane and a method of manufacturing an electronic device capable of adjusting the transmittance of light to make the luminance of an image more uniform in a display plane.

Additional aspects will be set forth in the detailed description which follows, and, in part, will be apparent from the disclosure, or may be learned by practice of the inventive concept.

According to exemplary embodiments, an electronic device includes: a light source which provides light; and a variable light control member which adjusts transmittance of the provided light. The variable light control member includes: a base substrate including a plurality of unit areas; a thin-film transistor (TFT) which is disposed on the base substrate; and a deformable lens layer having lens portion disposed on the base substrate in association with at least one of the unit areas, the lens portion being deformable by a control signal of the TFT.

According to exemplary embodiments, there is provided a method of controlling light transmittance of an electronic device, the electronic device including a light source which provides light and a variable light control member disposed on the light source, the method including: measuring transmittance of light provided from the light source through the variable light control member; and deforming a lens portion according to the measured transmittance so as to alter the transmittance. The variable light control member includes: a base substrate including a plurality of unit areas; a thin-film transistor (TFT) which is disposed on the base substrate; and a deformable lens layer having lens portion disposed on the base substrate in association with at least one of the unit areas, the lens portion being deformable by a control signal of the TFT.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a diagram illustrating a configuration of an electronic device associated with a display, according to one or more exemplary embodiments.

FIG. 2 is a schematic diagram illustrating the configuration of a base substrate of a variable light control member of FIG. 1, according to one or more exemplary embodiments.

FIG. 3 is a cross-sectional view of the variable light control member corresponding to one unit area of FIG. 2, according to one or more exemplary embodiments.

FIG. 4 is a circuit diagram of one unit area of FIG. 2, according to one or more exemplary embodiments.

FIG. 5 is a diagram illustrating a process of adjusting the transmittance of light provided from the light providing device of FIG. 1 to the variable light control member of FIG. 1, according to one or more exemplary embodiments.

FIG. 6 is a schematic cross-sectional view of an electronic device including a display module, according to one or more exemplary embodiments.

FIG. 7 is a diagram illustrating a process of adjusting the transmittance of light provided from the light providing device of FIG. 6 to the variable light control member of FIG. 6, according to one or more exemplary embodiments.

FIG. 8 illustrates another example of FIG. 7, according to one or more exemplary embodiments.

FIG. 9 is a schematic cross-sectional view of an electronic device, according to one or more exemplary embodiments.

FIG. 10 is a schematic cross-sectional view of an electronic device, according to one or more exemplary embodiments.

FIG. 11 is a schematic cross-sectional view of an electronic device, according to one or more exemplary embodiments.

FIG. 12 is a schematic cross-sectional view of an electronic device, according to one or more exemplary embodiments.

FIG. 13 is a schematic cross-sectional view of an electronic device, according to one or more exemplary embodiments.

FIG. 14 is a flowchart illustrating a method of manufacturing an electronic device, according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

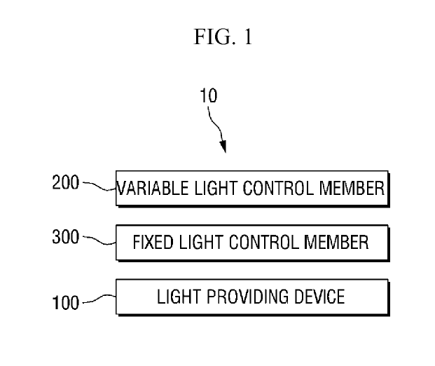

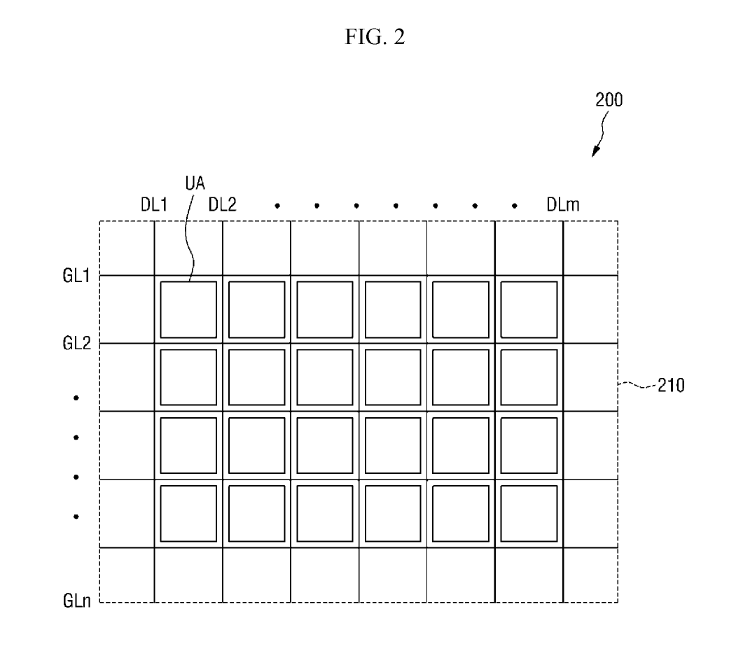

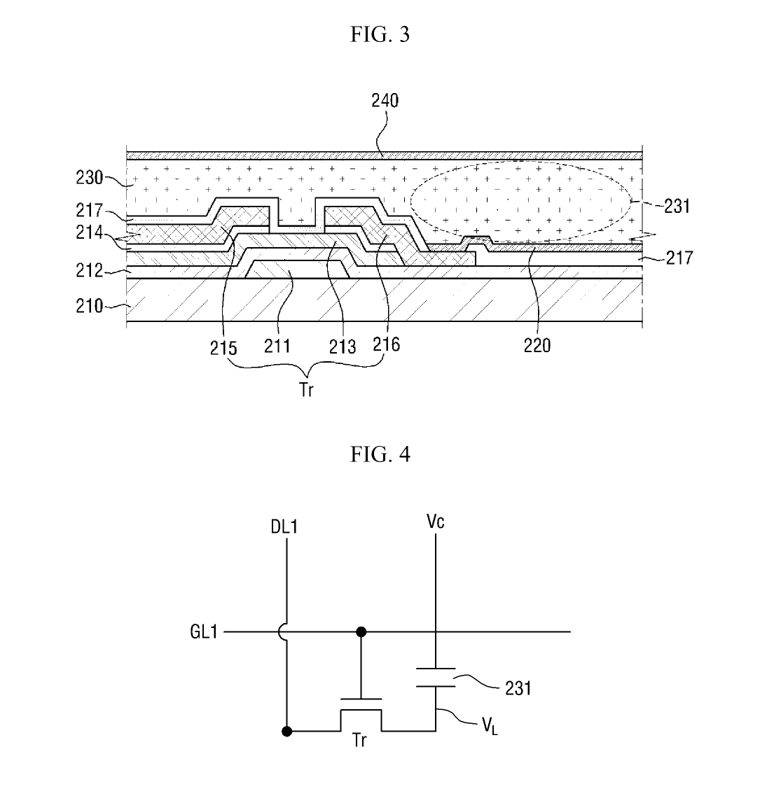

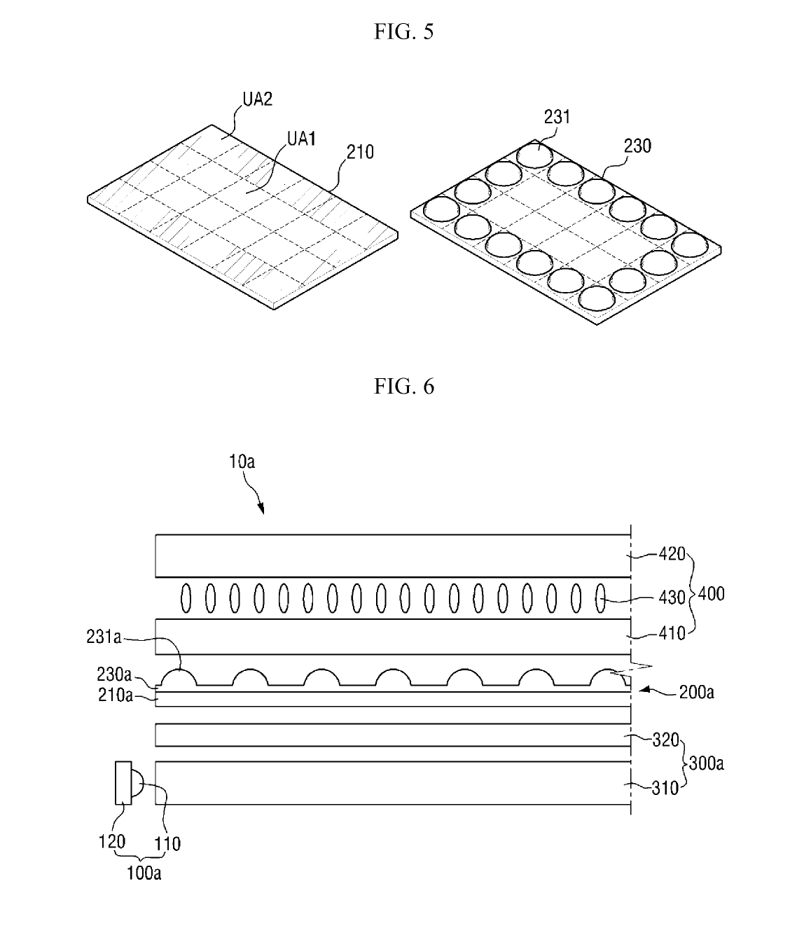

FIG. 1 is a diagram illustrating a configuration of an electronic device associated with a display, according to one or more exemplary embodiments. FIG. 2 is a schematic diagram illustrating the configuration of a base substrate of a variable light control member of FIG. 1, according to one or more exemplary embodiments. FIG. 3 is a cross-sectional view of the variable light control member corresponding to one unit area of FIG. 2, according to one or more exemplary embodiments. FIG. 4 is a circuit diagram of one unit area of FIG. 2, according to one or more exemplary embodiments. FIG. 5 is a diagram illustrating a process of adjusting the transmittance of light provided from the light providing device of FIG. 1 to the variable light control member of FIG. 1, according to one or more exemplary embodiments.

Referring to FIG. 1, electronic device 10 may be a lighting device that emits light or a display device that displays an image using light. The electronic device 10 includes a light providing device 100 and a variable light control member 200. The electronic device 10 may further include a light control member, e.g., a fixed light control member 300, disposed between the light providing device 100 and the variable light control member 200.

The light providing device 100 generates and provides light and may include, e.g., a light source. The light source may be any one of an incandescent lamp, a halogen lamp, a fluorescent lamp, and a light-emitting diode (LED). However, aspects of the present invention are not limited as such.

The variable light control member 200 adjusts the transmittance of light received from the light providing device 100. The variable light control member 200, as shown in FIG. 3, may include the base substrate 210, a thin-film transistor (TFT) Tr, a first lens control electrode 220, a lens layer 230, and a second lens control electrode 240.

The base substrate 210 may be a glass substrate or an insulating substrate, for example. Referring to FIG. 2, the base substrate 210 may include a plurality of unit areas UA defined by a plurality of gate lines GL1 through GLn arranged on the base substrate 210 along a first direction D1 and a plurality of data lines DL1 through DLm arranged along a second direction D2 intersecting the first direction D1.

One of more TFT transistors (Tr) may be provided and the one or more TFT Tr may be disposed on the base substrate 210 in each unit area UA. The TFT Tr may include a gate electrode 211, a semiconductor layer 213, a source electrode 215, and a drain electrode 216 as shown in FIG. 3, for example. In FIG. 3 and FIG. 4, a case where the TFT Tr is disposed in a unit area UA defined by the first gate line GL1 and the first data line DL1 will be described as an example.

The gate electrode 211 is disposed on the base substrate 210 to be connected to the first gate line GL1. The gate electrode 211 may include a metal, an alloy, metal nitride, conductive metal oxide, or a transparent conductive material. The first gate line GL1 may be disposed on the base substrate 210 when the gate electrode 211 is formed. A gate insulating layer 212 may be disposed on the base substrate 210 to cover the first gate line GL1 and the gate electrode 211. The gate insulating layer 212 may include silicon nitride or silicon oxide.

The semiconductor layer 213 is disposed on the gate electrode 211 with the gate insulating layer 212 interposed therebetween. The semiconductor layer 213 may include an active layer provided on the gate insulating layer 212. When viewed from the top of a second lens control electrode 240 (e.g., a direction perpendicular to the surface of the second lens control electrode 240), the active layer is formed in an area corresponding to an area in which the source electrode 215 and the drain electrode 216 are formed and an area between the source electrode 215 and the drain electrode 216. An ohmic contact layer 214 may be disposed on the active layer. The ohmic contact layer 214 may be disposed between the active layer and the source electrode 215 and between the active layer and the drain electrode 216.

The source electrode 215 may be disposed on the base substrate 210 to be connected to the first data line DL1 and may overlap at least part of the gate electrode 211 when viewed from the top of the second lens control electrode 240. The drain electrode 216 may be separated from the source electrode 215 and may overlap at least part of the gate electrode 211 when viewed from the top of the second lens control electrode 240.

The source electrode 215 and the drain electrode 216 may include a metal, an alloy, metal nitride, conductive metal oxide, or a transparent conductive material. Here, the source electrode 215 and the drain electrode 216 may partially overlap the semiconductor layer 213 in an area excluding the area between the source electrode 215 and the drain electrode 216 when viewed from the top of the second lens control electrode 240.

A first insulating layer 217 may be disposed on the source electrode 215, exposed portions of the ohmic contact layer 214, and the drain electrode 216 to cover the TFT Tr. The first insulating layer 217 may have a through hole that exposes a portion of the drain electrode 216. The first insulating layer 217 may be disposed on gate insulating layer 212. The first insulating layer 217 may include, e.g., silicon nitride or silicon oxide.

The first lens control electrode 220 is disposed on the first insulating layer 217 and is connected to the drain electrode 216 exposed through the through hole of the first insulating layer 217. The first lens control electrode 220 may include a transparent conductive material such as indium tin oxide (ITO).

The lens layer 230 may be disposed on the TFT Tr, more specifically, on the first insulating layer 217 and the first lens control electrode 220. The lens layer 230 may include a shape memory polymer that can be deformed by a voltage applied through the first lens control electrode 220 and the second lens control electrode 240. For example, the lens layer 230 may be made of any one of polyether urethane, polynorbornene, trans-polyisoprene, polyurethane and polyethylene and any one of carbon nanotube and carbon nanofiber.

In the lens layer 230, a lens portion 231 which contacts the first lens control electrode 220 may be disposed in each unit area UA or in more than one unit areas UA of the base substrate 210, in a regular or irregular pattern. If the lens portion 231 is disposed in more than one unit areas UA, the TFT Tr may be placed to correspond to the disposition of the lens portion 231. According to an exemplary embodiment of the present invention, if the lens portion 231 is disposed in one unit area UA among four adjacent unit areas UAs and the lens portion 231 is not disposed in the other three unit areas UAs, the TFT Tr may also be disposed in the unit area UA in which the lens portion 231 is disposed and the TFT Tr may not be disposed in the other three unit areas UAs.

In the process of manufacturing the electronic device 10, the transmittance of light provided from the light providing device 100 to the variable light control member 200 may be measured. If the result of measurement indicates that the transmittance of the light needs to be adjusted, the lens portion 231 may be deformed by the control of the TFT Tr so as to substantially adjust the transmittance of the light received from the light providing device 100. The transmittance of the light can be evaluated by measuring the luminance of the light.

For example, referring to FIG. 5, if a first luminance of light provided to each first unit area UA1 among the unit areas UA of the base substrate 210 is different from second luminance of light provided to each second unit area UA2 (a hatched area), the lens portion 231 located in each second unit area UA2 may be deformed by the control of the TFT Tr, such that the second luminance of the light provided to each second unit area UA2 becomes equal to the first luminance of the light provided to each first unit area UA1.

In an example, if the second luminance is smaller than the first luminance, it is required to increase the second luminance for better display quality. Accordingly, the TFT Tr may control the lens portion 231 located at a position corresponding to each second unit area UA2 of the base substrate 210 to become more convex than the lens portion 231 located at a position corresponding to each first unit area UA1 of the base substrate 210. In the lens layer 230 of FIG. 5, the lens portion 231 located at the position corresponding to each second unit area UA2 of the base substrate 210 has a convex shape, and the lens portion 231 located at the position corresponding to each first unit area UA1 of the base substrate 210 has a flat shape. As the lens portion 231 becomes more convex, its light collection rate increases, thereby increasing the luminance of light provided from the light providing device 100.

In FIG. 5, if light provided from the light providing device 100 to the variable light control member 200 has third luminance (between the first luminance and the second luminance) in each third unit area, the lens portion 231 located at a position corresponding to each third unit area of the base substrate 210 may be more convex than the lens portion 231 located at the position corresponding to each first unit area UA1 of the base substrate 210 and may be less convex than the lens portion 231 located at the position corresponding to each second unit area UA2 of the base substrate 210. In this example, the measured luminance of a UA (UA1) is used to set the target luminance for UA2. The exemplary embodiments are not so limited. For example, a predetermined luminance can be used as a target value. Also, the overall luminance of the device could be measured and a target luminance for each UA could be computed based on the measured luminance, as another example. Various other luminance control algorithms are possible.

Referring to FIG. 3, the second lens control electrode 240 is disposed on the lens layer 230 to be connected to a common power supply voltage Vc (see FIG. 4). The second lens control electrode 240 may include a transparent conductive material such as ITO.

Referring to FIG. 4, for the deformation of the lens portion 231, the TFT Tr of the variable light control member 300 applies a voltage V_{L} corresponding to a data signal supplied through the first data line DL1 to an end of the lens portion 231 in response to a control signal supplied through the first gate line GL1. The other end of the lens portion 231 is electrically connected to the common power supply voltage Vc. Accordingly, the lens portion 231 may be deformed by a voltage between the two ends of the lens portion 231, which is V_{L}−V_{C} or V_{C}−V_{L}. For example, if the electric potential V_{L} (or the voltage V_{L} between the end of the lens portion 231 connected to the TFT Tr and ground) increases, the lens portion 231 may become more convex. Further, when the voltage V_{L} applied from the TFT Tr is greater than the common power supply voltage Vc, the lens portion 231 may become convex. On the contrary, when the voltage V_{L} applied from the TFT Tr is smaller than the common power supply voltage Vc, the lens portion 231 may become flat or concave.

The lens portion 231 deformation determined in the process of manufacturing the electronic device 10 may be applied when the electronic device 10 is driven in operation. To this end, the electronic device 10 may be configured such that the voltage V_{L} of the TFT Tr and the common power supply voltage Vc can also be applied to the lens portion 231 when the electronic device 10 is driven.

According to exemplary embodiments, a variable light control member includes a newly-formed lens layer having a lens portion having properties corresponding to the lens portion 231 deformed in the process of manufacturing the electronic device 10, which is applied to the electronic device 10 in place of or in addition to the variable light control member used during manufacture. In this case, it is not necessary to apply the voltage V_{L} of the TFT Tr and the common power supply voltage Vc to the lens portion when the electronic device 10 is driven.

The fixed light control member 300 may be disposed between the light providing device 100 and the variable light control member 200. Without being deformed, the fixed light control member 300 adjusts the transmittance of light received from the light providing device 100. The fixed light control member 300 may include at least one of a prism member, a light guide member, a diffusion member, a non-deformable lens member, a phase difference compensation member, and a polarizing member.

As described above, the electronic device 10 includes the variable light control member 200 which includes the lens layer 230 having the lens portion 231 deformable by the control of the TFT Tr. Therefore, the electronic device 10 can adjust the transmittance of light provided from the light providing device 100 to be more uniform, thereby making the luminance of the light more uniform in a display plane.

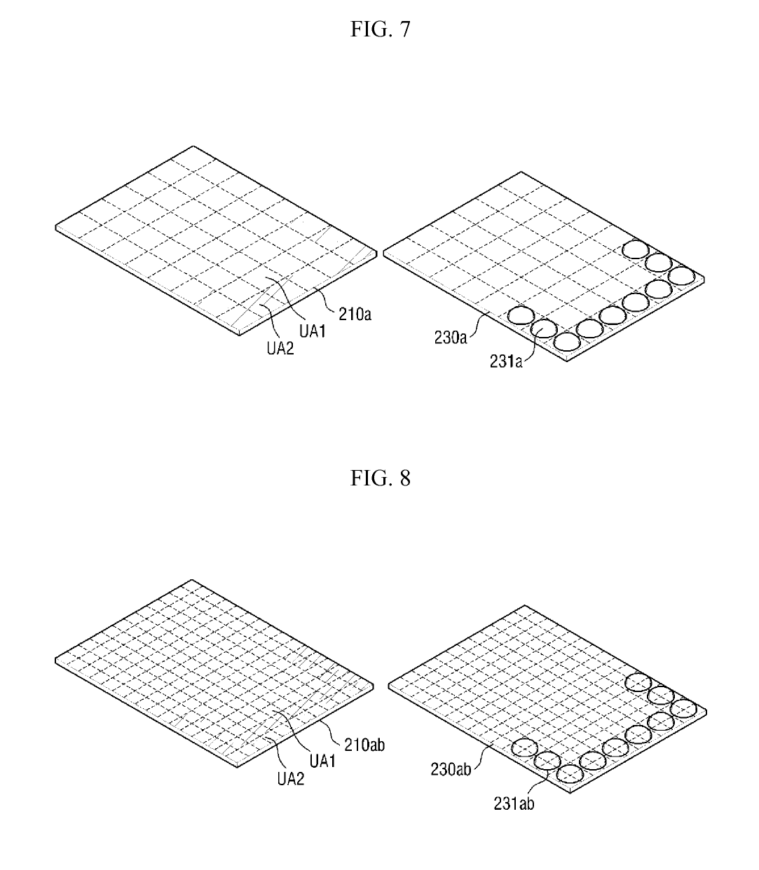

FIG. 6 is a schematic cross-sectional view of an electronic device including a display module, according to one or more exemplary embodiments. FIG. 7 is a diagram illustrating a process of adjusting the transmittance of light provided from the light providing device of FIG. 6 to the variable light control member of FIG. 6, according to one or more exemplary embodiments. FIG. 8 illustrates another example of FIG. 7, according to one or more exemplary embodiments.

Referring to FIG. 6, the electronic device 10a may be implemented as a liquid crystal display (LCD).

The electronic device 10a includes the light providing device 100a, a fixed light control member 300a, the variable light control member 200a, and an LCD panel 400.

The light providing device 100a generates light and provides the generated light to the LCD panel 400 via the fixed light control member 300a and the variable light control member 200a. The light providing device 100a includes one or more light sources 110 and a circuit board 120.

Each of the light sources 110 may generate light and may include a light source element, such as an LED.

The circuit board 120 may provide a space in which the light sources 110 are mounted and may include a wiring layer (not illustrated) that forms a path along which power for driving the light sources 110 is supplied to the light sources 110. The circuit board 120 may be of a bar type or another type.

Without being deformed, the fixed light control member 300a adjusts the transmittance of light received from the light providing device 100a. The fixed light control member 300a may include a light guide plate (LGP) 310 and a diffusion sheet 320.

The LGP 310 is disposed on at least one side of the light sources 110. The LGP 310 guides light supplied from the light sources 110 toward the LCD panel 400. In the drawings, the LGP 310 is shaped like a quadrangular plate. However, exemplary embodiments are not limited thereto, and the LGP 310 can have various shapes other than the quadrangular shape. The LGP 310 may include a transparent material that refracts light. In an exemplary embodiment, the transparent material may be, but is not limited to, transparent polymer resin such as polycarbonate or polymethyl methacrylate. In addition, the LGP 310 may be made of a rigid material. However, exemplary embodiments are not limited thereto, and the LGP 310 may also be made of a flexible material or include a flexible material.

The diffusion sheet 320 is disposed on the LGP 310 and diffuses light received from the LGP 310. Although not illustrated in the drawings, a prism sheet may be disposed on the diffusion sheet 320 and concentrate light diffused by the diffusion sheet 320 in a direction perpendicular to the LCD panel 400.

The variable light control member 200a is disposed on the fixed light control member 300a. The variable light control member 200a is deformed to adjust the transmittance of light received from the light providing device 100a via the fixed light control member 300a and provides the light with the adjusted transmittance to the LCD panel 400.

The variable light control member 200a may have the same configuration, function, and/or role as the variable light control member 200 of FIG. 2 through FIG. 4.

A plurality of unit areas UA (see FIG. 2) defined in a base substrate 210a may correspond to a plurality of pixels defined in the LCD panel 400, and a lens portion 231a of a lens layer 230a may be disposed in each unit area UA of the base substrate 210a. In this case, the variable light control member 200a may adjust the transmittance of light for each pixel of the LCD panel 400.

For example, referring to FIG. 7, if a first luminance of light provided to each first unit area UA1 among the unit areas UA of the base substrate 210a is different from second luminance of light provided to each second unit area UA2 (a hatched area), the lens portion 231a located in each second unit area UA2 may be deformed by the control of a corresponding TFT Tr (see FIGS. 3 and 4), such that the second luminance of the light provided to each second unit area UA2 becomes equal to the first luminance of the light provided to each first unit area UA1.

In an example, if the second luminance is smaller than the first luminance, it is required to increase the second luminance. Accordingly, the TFT Tr may control the lens portion 231a located at a position corresponding to each second unit area UA2 of the base substrate 210a to become more convex than the lens portion 231 a located at a position corresponding to each first unit area UA1 of the base substrate 210a. In the lens layer 230a of FIG. 7, the lens portion 231a located at the position corresponding to each second unit area UA2 of the base substrate 210a has a convex shape, and the lens portion 231a located at the position corresponding to each first unit area UA1 of the base substrate 210a has a flat shape, for example. As the lens portion 231a becomes more convex, its light collection rate increases, thereby increasing the luminance of light provided from the light providing device 100a. Other luminance control schemes are possible, as described above.

If a plurality of pixels defined in the LCD panel 400 are small in size, a plurality of unit areas UA (see FIG. 2) defined in a base substrate 210ab may correspond to the pixels defined in the LCD panel 400, and a lens portion 231ab of a lens layer 230ab (see FIG. 8 for an example) may be disposed in more than one unit areas UA of the base substrate 210ab, in a regular or irregular pattern. In this case, the variable light control member 200a may adjust the light transmittance of the LCD panel 400 for pixels corresponding to at least two unit areas UA.

For example, referring to FIG. 8, if first luminance of light provided to each first unit area UA1 among the unit areas UA of the base substrate 210ab is different from second luminance of light provided to each second unit area UA2 (a hatched area), the lens portion 231ab located in two or more second unit areas UA2 may be deformed by the control of a corresponding TFT Tr (see FIGS. 3 and 4), such that the second luminance of the light provided to each second unit area UA2 becomes equal to the first luminance of the light provided to the first unit area UA1.

In an example, if the second luminance is smaller than the first luminance, it may be necessary to increase the second luminance to improve the display quality. Accordingly, the TFT Tr may control one lens portion 231ab disposed to correspond to four second unit areas UA2 of the base substrate 210ab to become more convex than one lens portion 231ab disposed to correspond to four first unit areas UA1 of the base substrate 210ab. In the lens layer 230ab of FIG. 8, one lens portion 231ab disposed to correspond to four second unit areas UA2 has a convex shape, and one lens portion 231ab disposed to correspond to four first unit areas UA1 of the base substrate 210ab has a flat shape. As the lens portion 231ab becomes more convex, its light collection rate increases, thereby increasing the luminance of light provided from the light providing device 100a. Other luminance control schemes are possible, as described above.

Referring to FIG. 6, the LCD panel 400 is disposed on the variable light control member 200a. The LCD panel 400 includes a plurality of pixels. The pixels may be arranged in a matrix. The LCD panel 400 may include a first panel 410 and a second panel 420 which face each other. The first panel 410 and the second panel 420 may be coupled to each other by a sealing member (not illustrated). A liquid crystal layer 430 may be interposed between the first panel 410 and the second panel 420.

The LCD panel 400 controls the arrangement of liquid crystal molecules of the liquid crystal layer 430 and displays an image by adjusting the amount of light received from the light providing device 100a via the fixed light control member 300a and the variable light control member 200a. Here, the LCD panel 400 receives light controlled by the variable light control member 200a to have relatively more uniform transmittance. Therefore, the LCD panel 400 can display an image with more uniform luminance by adjusting the amount of light by controlling the arrangement of the liquid crystal molecules.

A case where the variable light control member 200a adjusts the transmittance of light from the light providing device 100a to be more uniform has been described above. However, the transmittance of light provided by the light providing device 100a when the electronic device 10a is driven can be changed based on image data for displaying an image on the LCD panel 400. Accordingly, this can make local dimming driving possible. For example, a portion of the display screen may be dimmed while another portion of the display screen may be relatively more bright by individually controlling convexity of lens portions 231a.

As described above, the electronic device 10a includes the variable light control member 200a which includes the lens layer 230a having the lens portion 231a deformable by the control of the TFT Tr. Thus, the electronic device 10a may adjust the transmittance of light provided from the light providing device 100a to be more uniform.

In the electronic device 10a, since light having more uniform transmittance is provided to the LCD panel 400 through the adjustment by the variable light control member 200a, an image having more uniform luminance can be displayed on the LCD panel 400.

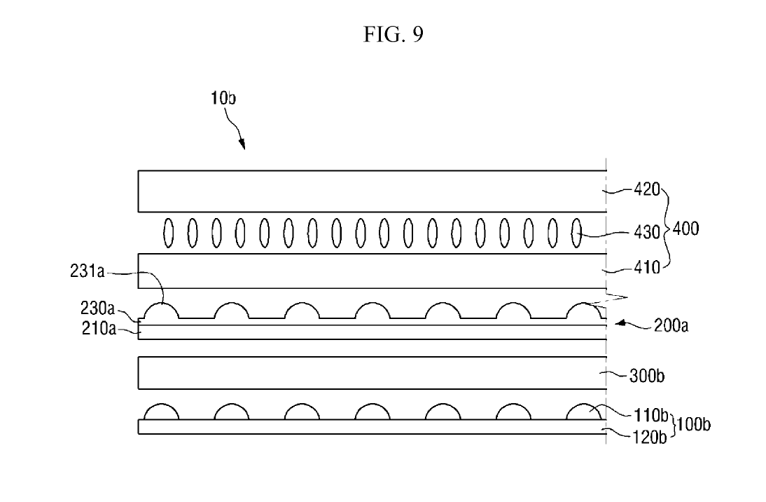

FIG. 9 is a schematic cross-sectional view of an electronic device, according to one or more exemplary embodiments.

Referring to FIG. 9, the electronic device 10b is implemented as an LCD, like the electronic device 10a of FIG. 6. The electronic device 10b may have the same configuration, function, and/or role as the electronic device 10a except for the configuration of a light providing device 100b and a fixed light control member 300b. Accordingly, only the light providing device 100b and the fixed light control member 300b of the electronic device 10b will be described below in more detail.

The light providing device 100b generates light and provides the generated light to an LCD panel 400 via the fixed light control member 300b and a variable light control member 200a. The light providing device 100b includes one or more light sources 110b and a circuit board 120b.

The light sources 110b are similar to the light sources 110 of FIG. 6. However, while the light sources 110 of FIG. 6 are disposed on a side of the LCD panel 400, the light sources 110b are disposed under the LCD panel 400. In this case, the number of the light sources 110b may be greater than that of the light sources 110 of FIG. 6.

The circuit board 120b may be similar to the circuit board 120 of FIG. 6. Further, the circuit board 120b may be disposed under the light sources 110b.

The fixed light control member 300b is similar to the fixed light control member 300a of FIG. 6. However, since the light sources 110b are disposed under the LCD panel 400 to face the LCD panel 400, the LGP 310 of FIG. 6 may be omitted, and the fixed light control member 300b may be formed as a diffusion plate that diffuses light provided from the light sources 110b.

As described above, the electronic device 10b includes the variable light control member 200a which includes a lens layer 230a having a lens portion 231a deformable by the control of a TFT. Thus, the electronic device 10b can adjust the transmittance of light provided from the light providing device 100b to be more uniform.

In the electronic device 10b, since light having more uniform transmittance is provided to the LCD panel 400 through the adjustment by the variable light control member 200a, an image having more uniform luminance can be displayed on the LCD panel 400.

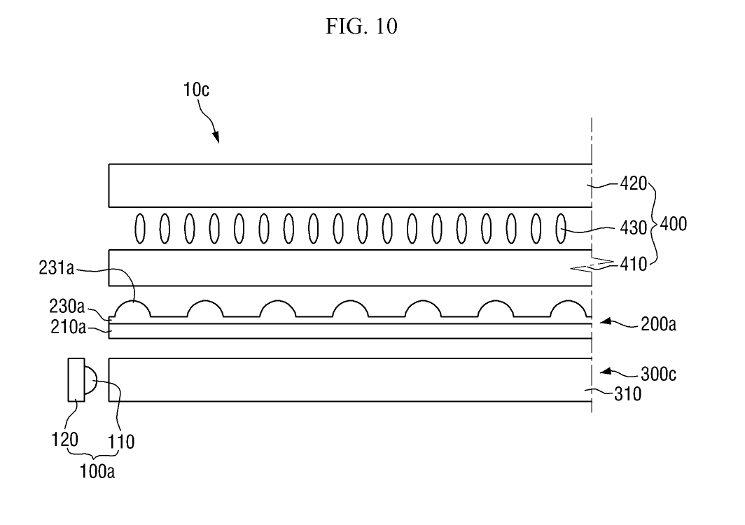

FIG. 10 is a schematic cross-sectional view of an electronic device, according to one or more exemplary embodiments.

Referring to FIG. 10, the electronic device 10c is implemented as an LCD, like the electronic device 10a of FIG. 6. The electronic device 10c may have the same configuration, function, and/or role as the electronic device 10a except for a fixed light control member 300c. Accordingly, only the fixed light control member 300c of the electronic device 10c will be described below in more detail.

The fixed light control member 300c is similar to the fixed light control member 300a of FIG. 6. However, the fixed light control member 300c may include the LGP 310 only and may not include the diffusion sheet 320 of FIG. 6. In this case, the thickness of the electronic device 10c may be reduced.

As described above, the electronic device 10c includes a variable light control member 200a which includes a lens layer 230a having a lens portion 231a deformable by the control of a TFT. Thus, the electronic device 10c may adjust the transmittance of light provided from a light providing device 100a to be relatively more uniform.

In the electronic device 10c, since light having more uniform transmittance is provided to an LCD panel 400 through the adjustment by the variable light control member 200a, an image having more uniform luminance can be displayed on the LCD panel 400.

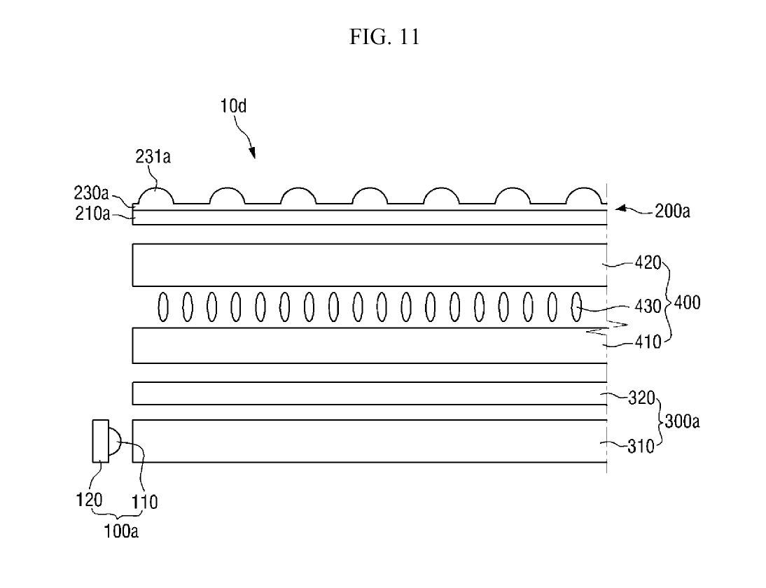

FIG. 11 is a schematic cross-sectional view of an electronic device, according to one or more exemplary embodiments.

Referring to FIG. 11, the electronic device 10d is implemented as an LCD, like the electronic device 10a of FIG. 6. The electronic device 10d may have the same configuration, function, and/or role as the electronic device 10a except for the position of a variable light control member 200a. Specifically, in the electronic device 10d, the variable light control member 200a is disposed on an LCD panel 400. In this case, the variable light control member 200a adjusts the transmittance of light output from the LCD panel 400. After the light passes through the LCD panel 400 from the fixed light control member 300a, the variable light control member 200a adjusts the transmittance of the display image of the LCD panel 400, thereby making the luminance of an image displayed on the LCD panel 400 more uniform. As a result, the display quality of the electronic device 10d can be improved.

As described above, the electronic device 10d includes the variable light control member 200a which includes a lens layer 230a having a lens portion 231a deformable by the control of a TFT. Thus, the electronic device 10d may adjust the transmittance of light output from the LCD panel 400 to be more uniform.

In the electronic device 10d, since light having more uniform transmittance is output from the LCD panel 400 through the adjustment by the variable light control member 200a, an image having more uniform luminance can be displayed on the LCD panel 400. As a result, display quality can be improved.

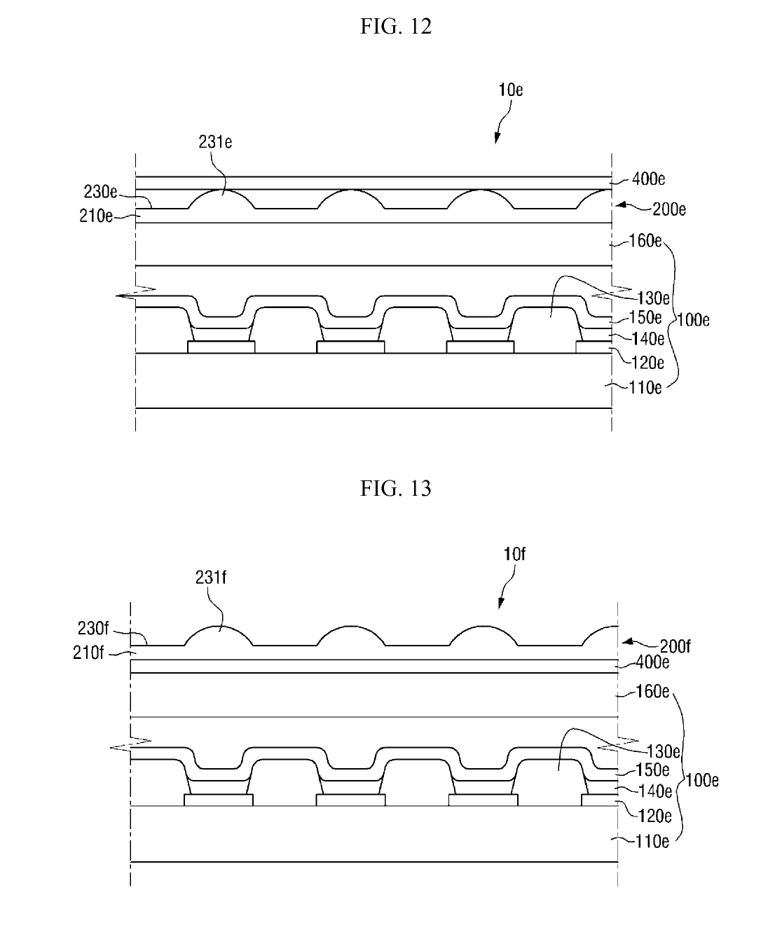

FIG. 12 is a schematic cross-sectional view of an electronic device, according to one or more exemplary embodiments.

Referring to FIG. 12, the electronic device 10e is implemented as an organic light-emitting display.

The electronic device 10e includes a light providing device 100e and a variable light control member 200e.

The light providing device 100e is an organic light-emitting display panel and includes a first substrate 110e, a first electrode 120e, a pixel defining layer 130e, an organic layer 140e, a second electrode 150e, and a second substrate 160e.

The first substrate 110e may include an insulating substrate. The insulating substrate may be made of or include a transparent glass material containing SiO2 as its main component. In some embodiments, the insulating substrate may be made of or include an opaque material or a plastic material. Further, the insulating substrate may be a flexible substrate.

Although not illustrated in the drawings, the first substrate 110e may further include other structures formed on the insulating substrate. Examples of the structures include wirings, electrodes, and insulating layers. If the electronic device 10e is an active matrix organic light-emitting display, the first substrate 110e may include a plurality of TFTs disposed on the insulating substrate. Each of at least some of the TFTs may have a drain electrode electrically connected to the first electrode 120e. Each of the TFTs may have an active region made of silicon or oxide semiconductor.

The first electrode 120e may be disposed on the substrate 110e in each pixel. The first electrode 120e may be an anode which provides holes or a cathode which provides electrons to the organic layer 140e in response to a signal transmitted to a drain electrode of a corresponding TFT. In the current embodiment, a case where the first electrode 120e is an anode will be described as an example but the first electrode 120e may be a cathode in a different configuration. If the first electrode 120e is used as a reflective electrode, the electronic device 10e may be a top emission organic light-emitting display in which light emerging from the organic layer 140e is emitted toward the second electrode 150e.

The pixel defining layer 130e may be disposed on the first substrate 110e having the first electrode 120e. The pixel defining layer 130e may be disposed at a boundary of each pixel to define each pixel. In addition, the pixel defining layer 130e may define an opening that provides a space in which the organic layer 140e is to be placed. The first electrode 120e is exposed by the opening of the pixel defining layer 130e. Here, a side of the first electrode 120e extends toward the pixel defining layer 130e to partially overlap the pixel defining layer 130e. In each area in which the pixel defining layer 130e and the first electrode 120e overlap each other, the pixel defining layer 130e may be disposed on the first electrode 120e based on the first substrate 110e.

The pixel defining layer 130e may include an insulating material. Specifically, the pixel defining layer 130e may include at least one organic material selected from the group consisting of benzocyclobutene (BCB), polyimide (PI), polyamide (PA), acrylic resin, and phenolic resin. In another example, the pixel defining layer 130e may include an inorganic material, such as silicon nitride.

The organic layer 140e may be disposed on the first electrode 120e. Specifically, the organic layer 140e may be disposed in the opening of the pixel defining layer 130e and may extend to partially cover a portion of the pixel defining layer 130e, e.g., an upper portion of the pixel defining layer 130e and a side portion of the pixel defining layer 130e. The organic layer 140e may include an organic light-emitting layer which substantially emits light when holes received from the first electrode 120e and electrons received from the second electrode 150e recombine. More specifically, holes and electrons provided to the organic light-emitting layer may combine to form excitons. When the excitons change from an excited state to a ground state, the organic light-emitting layer may emit light.

The second electrode 150e may be disposed on the organic layer 140e and may be a cathode providing electrons to the organic layer 140e or an anode providing holes to the organic layer 140e. In the current embodiment, a case where the second electrode 150e is a cathode will be described as an example but the second electrode 150e may be an anode in a different configuration.

The second substrate 160e may be made of or include an insulating substrate. A spacer (not illustrated) may be disposed between the second substrate 160e and the second electrode 150e on the pixel defining layer 130e. In some other embodiments of the present invention, the second substrate 160e can be omitted. In this case, an encapsulation layer made of an insulating material may protect the entire structure by covering the entire structure.

The variable light control member 200e may have the same configuration, function, and/or role as the variable light control member 200 of FIG. 2 through FIG. 4.

A plurality of unit areas UA (see FIG. 2) defined in a base substrate 210e may correspond to a plurality of pixels defined in the organic light-emitting display panel, and a lens portion 231e of a lens layer 230e may be placed in each unit area UA of the base substrate 210e. In this embodiment, the variable light control member 200e may adjust the transmittance of light for each pixel of the organic light-emitting display panel.

Accordingly, when the organic light-emitting layer of the organic light-emitting display emits light in response to a current flowing from the anode to the cathode in each pixel, if the magnitude of the current flowing from the anode to the cathode differs in each pixel due to, e.g., unwanted internal resistance, the variable light control member 200e can adjust the transmittance of light received from the organic light-emitting display panel to be more uniform across the display screen.

A polarizer 400e may be attached onto the variable light control member 200e to prevent or reduce reflection of external light. The polarizer 400e may include an adhesive at each portion that contacts the variable light control member 200e. Therefore, the lens portion 231e of the variable light control member 200e may be deformed by the elasticity of the adhesive without being greatly constrained by space.

As described above, the electronic device 10e includes the variable light control member 200e which includes the lens layer 230e having the lens portion 231e deformable by the control of a TFT. Thus, the electronic device 10e may adjust the transmittance of light emitted from the organic light-emitting display panel (i.e., the light providing device 100e).

In the electronic device 10e, since light having more uniform transmittance is output from the organic light-emitting display panel (i.e., the light providing device 100e) through the adjustment by the variable light control member 200e, an image having more uniform luminance may be displayed on the organic light-emitting display panel. As a result, display quality can be improved.

FIG. 13 is a schematic cross-sectional view of an electronic device, according to one or more exemplary embodiments.

Referring to FIG. 13, the electronic device 10f is implemented as an organic light-emitting display, like the electronic device 10e of FIG. 12. The electronic device 10f may have the same configuration, function, and/or role as the electronic device 10e except for the position of a variable light control member 200e of FIG. 12. Accordingly, only the variable light control member 200f of the electronic device 10f will be described below in more detail.

The variable light control member 200f may be similar to the variable light control member 200e of FIG. 12. However, the variable light control member 200f is disposed on a polarizer 400e. In this embodiment, the deformation of a lens portion 231f may be easily controlled.

As described above, the electronic device 10f includes the variable light control member 200f which includes a lens layer 230f having the lens portion 231f deformable by the control of a TFT. Thus, the electronic device 10f may adjust the transmittance of light emitted from an organic light-emitting display panel (i.e., a light providing device 100e).

In the electronic device 10f, since light having more uniform transmittance is output from the organic light-emitting display panel (i.e., the light providing device 100e) through the adjustment by the variable light control member 200f, an image having more uniform luminance may be displayed on the organic light-emitting display panel. As a result, display quality can be improved.

Hereinafter, a method of manufacturing electronic devices according to the above-described exemplary embodiments of the present invention will be described.

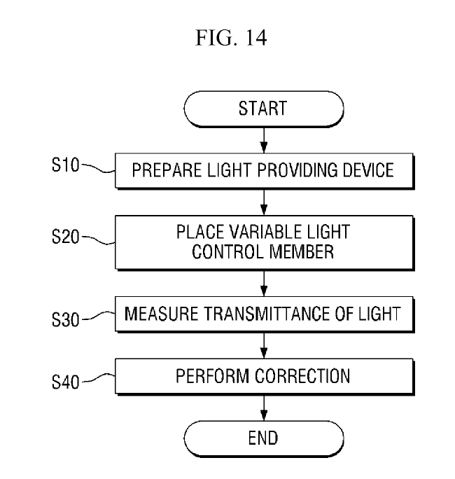

FIG. 14 is a flowchart illustrating a method of manufacturing an electronic device, according to one or more exemplary embodiments.

Referring to FIG. 14, the method of manufacturing an electronic device may include preparing a light providing device (operation S10), placing a variable light control member (operation S20), measuring the transmittance of light (operation S30), and performing correction of the transmittance (operation S40).

Referring to FIG. 14, in the preparing of the light providing device (in accordance with the exemplary embodiments (such as those described above), e.g., the light providing device, e.g., 100 which generates and provides light may be prepared (operation S10). The light providing devices have been described above in detail, and thus further description thereof will be omitted.

Operation S20 places a variable light control member on the light providing device.

The variable light control member may include, for example, a base substrate 210 in which a plurality of unit areas UA are defined, a plurality of TFTs Tr which are disposed on the base substrate 210, and a lens layer 230 having a lens portion 231 which is placed on the base substrate 210 in each unit area UA or every two or more unit areas UA and can be deformed by the control of a corresponding TFT Tr.

Referring to FIG. 14, in the measuring of the transmittance of the light (operation S30), the transmittance of light provided from the light providing device to the variable light control member is measured. The transmittance of the light may be evaluated by measuring the luminance of the light. The luminance of the light may be measured by a luminance measurement device.

Referring to FIG. 14, in the performing of correction of the transmittance of the light (operation S40), the transmittance of the light is adjusted by deforming the lens portion according to the measured transmittance of the light.

Accordingly, the transmittance of the light provided from the light providing device to the variable light control member 200 may be adjusted to be more uniform. As a result, the luminance of the light also becomes more uniform.

Although not illustrated in the drawings, the method of manufacturing an electronic device may further include placing a fixed light control member, which adjusts the transmittance of light, between the light providing device and the variable light control member disposed on the light providing device, based on measurements and corrections determined during manufacture.

Exemplary embodiments provide at least one of the following advantages.

An electronic device according to exemplary embodiments can include a variable light control member which includes a lens layer having a lens portion deformable by the control of a TFT. Thus, the electronic device can adjust the transmittance of light provided from a light providing device to be more uniform, thereby making the luminance of the light more uniform.

It should be understood that the exemplary embodiments described therein should be considered in a descriptive sense only and not for purposes of limitation. Descriptions of features or aspects within each embodiment should typically be considered as available for other similar features or aspects in other embodiments.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An electronic device comprising:
a light source which provides light; and
a variable light control member which adjusts transmittance of the provided light,
wherein the variable light control member comprises:
a base substrate comprising a plurality of unit areas;
a thin-film transistor (TFT) which is disposed on the base substrate; and
a deformable lens layer having lens portion disposed on the base substrate in association with at least one of the unit areas, the lens portion being deformable by a control signal of the TFT.

2. The electronic device of claim 1, wherein the lens portion is disposed between first and second control electrodes, the first lens control electrode disposed between the TFT and the lens portion.

3. The electronic device of claim 1, wherein the lens layer comprises a shape memory polymer.

4. The electronic device of claim 1, wherein the lens layer comprises any one of polyether urethane, polynorbornene, trans-polyisoprene, polyurethane and polyethylene and comprises any one of carbon nanotube and carbon nanofiber.

5. The electronic device of claim 1, wherein the base substrate comprises a glass substrate or an insulating substrate.

6. The electronic device of claim 1, further comprising a fixed light control member which is disposed between the light source and the variable light control member, and wherein the variable light control member is disposed on the light source,
wherein the fixed light control member controls the transmittance of the light without being deformed.

7. The electronic device of claim 6, wherein the fixed light control member comprises at least any one of a prism member, a light guide member, a diffusion member, a non-deformable lens member, a phase difference compensation member, and a polarizing member.

8. The electronic device of claim 6, further comprising a liquid crystal display (LCD) panel which is disposed on the variable light control member,
wherein a plurality of pixels corresponding to the unit areas are defined in the LCD panel.

9. The electronic device of claim 8, wherein the light source comprises a circuit board which supplies power for driving the light source, and
wherein the fixed light control member comprises a light guide plate (LGP), which is disposed on at least a side of the light source, and a diffusion sheet, which is disposed between the LGP and the variable light control member.

10. The electronic device of claim 8, wherein the light source comprises a circuit board which supplies power for driving the light source, and
wherein the fixed light control member comprises a diffusion plate which is disposed between the light source and the variable light control member, and wherein the variable light control member is disposed on the light source.

11. The electronic device of claim 8, wherein the light source comprises a circuit board which supplies power for driving the light source, and
wherein the fixed light control member comprises an LGP which is disposed on at least a side of the light source and faces the variable light control member.

12. The electronic device of claim 6, further comprising a liquid crystal display (LCD) panel which is disposed between the fixed light control member and the variable light control member,
wherein a plurality of pixels corresponding to the unit areas are defined in the LCD panel.

13. The electronic device of claim 1, wherein the light source comprises an organic light-emitting display panel in which pixels corresponding to the unit areas are defined, and
wherein the organic light-emitting display panel comprises an organic light-emitting layer disposed in each of the pixels.

14. A method of controlling light transmittance of an electronic device, the electronic device comprising a light source which provides light and a variable light control member disposed on the light source, the method comprising:
measuring transmittance of light provided from the light source through the variable light control member; and
deforming a lens portion according to the measured transmittance so as to alter the transmittance,
wherein the variable light control member comprises:
a base substrate comprising a plurality of unit areas;
a thin-film transistor (TFT) which is disposed on the base substrate; and
a deformable lens layer having the lens portion disposed on the base substrate in association with at least one of the unit areas, the lens portion being deformable by a control signal of the TFT.

15. The method of claim 14, wherein the deforming comprises:
deforming the lens portion such that a difference between luminance of a first unit area and luminance of a second unit area, associated with the TFT, is reduced.

16. The method of claim 15, wherein, in response to a determination that measured luminance of the second unit area is lower than measured luminance of the first unit area, the lens portion is deformed to be more convex than a lens portion associated with the first unit area.

17. The method of claim 14, further comprising:
adjusting, by using a fixed light control member of the electronic device, a transmittance of light passing between the light source and the variable light control member,
wherein the fixed light control member comprises at least any one of a prism member, a light guide member, a diffusion member, an non-deformable lens member, a phase difference compensation member, and a polarizing member.

18. The method of claim 17, wherein a liquid crystal display(LCD) panel in which a plurality of pixels corresponding to unit areas are defined is placed on the variable light control member, and
wherein the light source comprises a circuit board which supplies power for driving the light source.

19. The method of claim 17, wherein a liquid crystal display(LCD) panel in which a plurality of pixels corresponding to unit areas is placed between the fixed light control member and the variable light control member, and
wherein the light source comprises a circuit board which supplies power for driving the light source.

20. The method of claim 14, wherein the light source comprises an organic light-emitting display panel in which pixels corresponding to unit areas are defined, and
wherein the organic light-emitting display panel comprises an organic light-emitting layer disposed in each of the pixels.
